(19) United States
(12) Patent Application Publication
(10) Pub. No.: US 2007/0235776 A1
(43) Pub. Date: Oct. 11, 2007

(54) Forming memory arrays

(76) Inventor: Nuriel Amir, Moshav Arugot (IL)

Correspondence Address: TROP PRUNER & HU, PC, 1616 S. VOSS ROAD, SUITE 750, HOUSTON, TX, 77057-2631, US

(21) Appl. No.: 11/394,015

(22) Filed: Mar. 30, 2006

(51) Int. Cl. H01L 29/772; H01L 21/8234

(52) U.S. Cl. 257/288; 438/197

(57) ABSTRACT

Source strap cells which are manufactured in a very similar way to conventional memory cells may be utilized to enable connections to the source of a memory cell. In other words, the source and the drain may be contacted by vias which are arranged identically in some embodiments. This may result in greater symmetry, reduced die size, and greater manufacturing efficiencies in some embodiments.

### BACKGROUND

This invention relates generally to techniques and architectures for memory arrays.

In flash memory arrays, transistors are formed with source and drains. Typically, metal straps are used to connect to the drains, but a different structure is utilized to connect to the sources. As a result, the memory architecture is asymmetrical. Specifically, an enlarged area is provided where the word lines diverge to form a contact for the source.

This asymmetry results in larger footprint area and greater manufacturing complexity. A larger footprint and greater manufacturing complexity may result in higher costs.

Thus, there is a need for different ways to arrange and manufacture memories.

### BRIEF DESCRIPTION OF THE DRAWINGS

FIG. 1 is a partial, enlarged, top plan view of one embodiment of the present invention;

FIG. 2 is a partial, enlarged, cross-sectional view taken generally along the line 2-2 in FIG. 1 in accordance with one embodiment of the present invention;

FIG. 3 is a partial, enlarged, cross-sectional view taken generally along the line 3-3 in FIG. 1 in accordance with one embodiment of the present invention;

FIG. 4 is a partial, enlarged, cross-sectional view taken generally along the line 4-4 in FIG. 1 through the memory cell in accordance with one embodiment of the present invention;

FIG. 5 is a partial, enlarged, cross-sectional view taken generally along the line 5-5 in FIG. 1 through the memory cell in accordance with one embodiment of the present invention;

FIG. 6 is an enlarged, cross-sectional view corresponding to FIG. 2 but at an earlier stage of manufacture in accordance with one embodiment of the present invention; and

FIG. 7 is a system depiction in accordance with one embodiment of the present invention.

### DETAILED DESCRIPTION

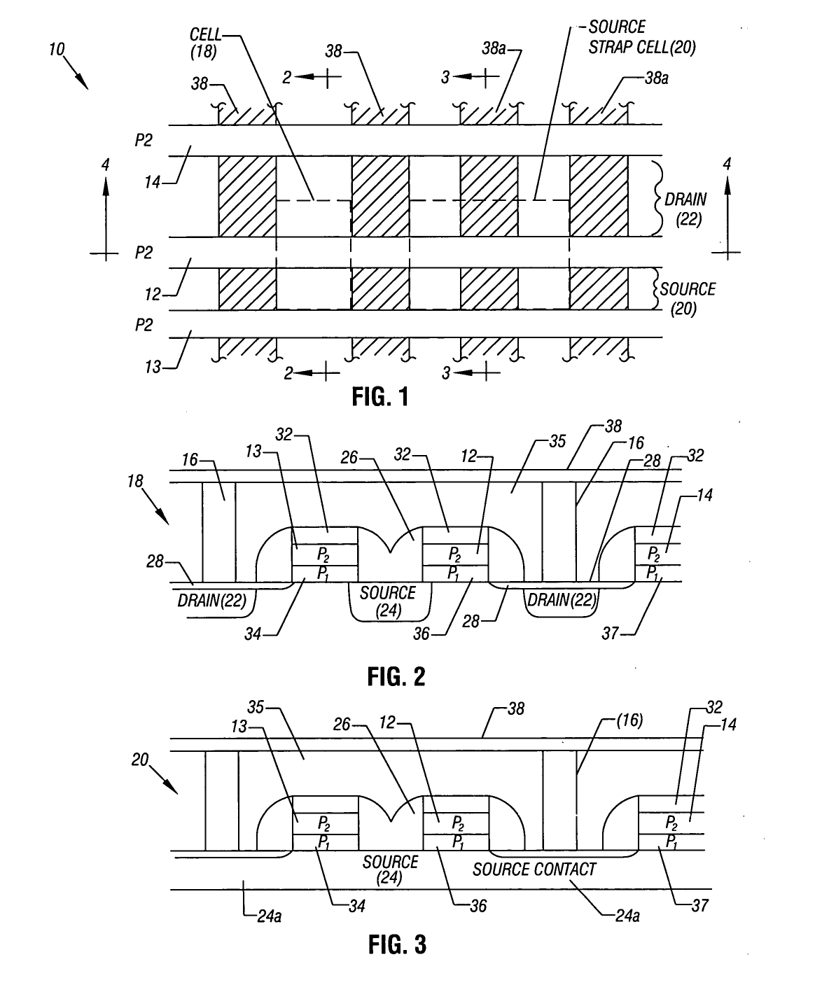

Referring to FIG. 1, a memory 10, such as a flash memory, may include a number of memory cells 18 separated by one or more source strap cells 20. In accordance with one embodiment of the present invention, the configuration of a memory cell 18 and the source strap cell 20 is substantially similar so that manufacturing is facilitated and footprint is reduced in some cases. Specifically, diverging word lines for source connections may be avoided in some embodiments and a source strap cell 20 may be made symmetrically and consistently with the memory cells 18.

A set of three spaced word lines 12, 13, and 14 are depicted. Each word line 12, 13, or 14 may, for example, be formed of polysilicon, silicide, salicide, or even metal in some cases.

A drain 22 may be formed between the word lines 12 and 14 in the cell 18 region. A source 20 may be formed between the word lines 12 and 13.

Transverse bitlines 38, 38a are also shown in FIG. 1. In one embodiment, the word lines and bitlines are straight and free of any divergence or offset region for a source contact.

Conventionally, polysilicon lines make up the word lines and the metal lines, which run transverse thereto, make up the bitlines. However, other conventions may also be utilized.

Referring to FIG. 2, word lines 12, 13, and 14 may be formed of the second level conductive material sometimes called poly2 (P2). The poly2 overlies a first or lower conductive word line layer commonly called the poly1 (P1) layer 34, 36, and 37. Between the poly1 layers 34 and 36 there is a source 24 and between the poly1 layer 36 and the poly1 layer 37 there may be a drain 22 associated with a tip or graded source drain junction 28. In some embodiments, the source 24 may be slightly deeper than the drain 22.

The drain 22 may be electrically connected to metal bitlines 38 by a via 16.

A cell stack may include a combination of a poly2 layer over a poly1 layer. In some embodiments, the poly2 layer may be overlaid by a salicide layer 32 for improved conduction. In other cases, the salicide layer 32 may be dispensed with. Also, over the salicide layer 32 may be an interlayer dielectric (ILDO) 35, in turn, covered by a lower metal layer commonly called a metal layer 39. Between the cell stacks including the word lines may be spacers, such as the spacers 26, which may be sidewall spacers in some embodiments.

Referring next to FIG. 3, a source strap cell 20 is shown. The cross-sectional configuration of a source strap cell 20, along the direction of the bitlines 38 (shown in FIG. 3), may be substantially similar to the cross-sectional depiction, shown in FIG. 2, along the direction of the bitlines 38 for the cell 18. Thus, the source strap cells 20 and the memory cells 18 may be formed in substantially similar ways so that greater symmetry is achieved. In some embodiments, this may result in manufacturing efficiencies and in reduced die sizes.

In one embodiment of the source strap cell 20, a source contact 24a merges with the source 24. However, in other embodiments, a gap may be maintained between the source contact 24a and the source 24, particularly in the region below the word line 36. In other aspects, the source strap cell 20 is substantially similar to the cell 18 as viewed along the direction of the bitlines 39 and transverse to the direction of the word lines.

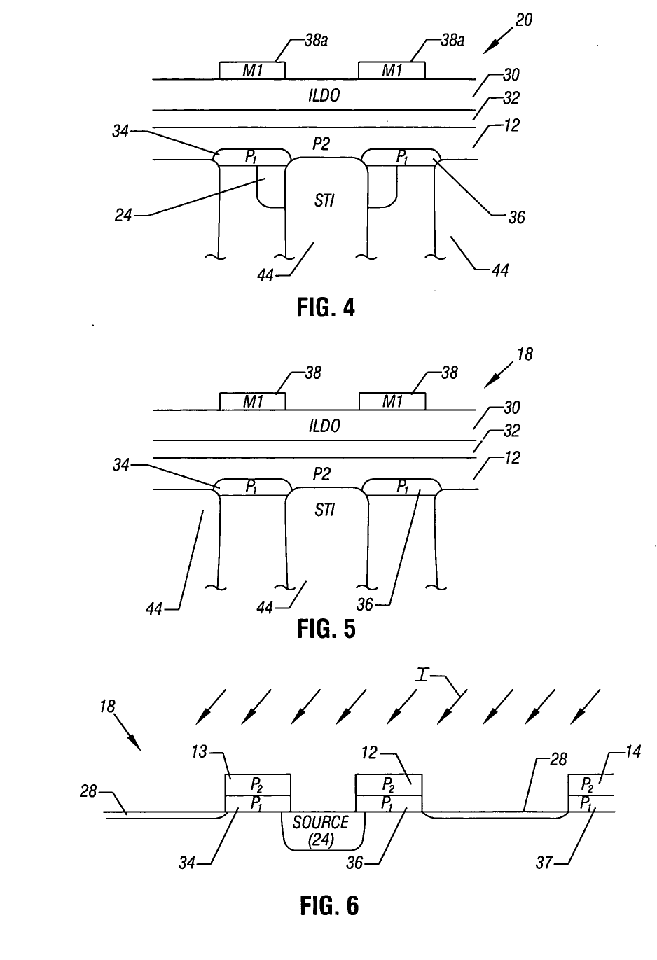

Referring to FIG. 5, the source strap cell 20 is depicted in a direction along the length of the word line 12 and transverse to the metal lines 38. The metal lines 38a, which may form the bitlines shown in FIG. 4, may overlie the interlayer dielectric 30 and the salicide layer 32, if present. The poly2 layer 12 is depicted over poly1 layers 34 and 36. Underlying the poly2 layer 12 may be a set of three spaced shallow trench isolation regions 44 alongside the poly1 layers 34 and 36. The source region 24 may appear in the area of a source strap cell 20 as indicated.

The memory cell 18 is generally similar including metal lines 38, interlayer dielectric 30, salicide 32, poly2 layer 12, poly1 layer 34, and shallow trench isolations 44. The only difference, in some embodiments of the present invention, is the absence of the source 24 in the area of the cell 18.

Referring to FIG. 6, in accordance with some embodiments of the present invention, the source contact 24a may be formed by an angled ion implant I. The implant I, which may be basically a source/drain implant, may be formed after the shallow tips 28, in some embodiments of the present invention, and after the gate stacks have been formed. In some cases, the source contact 24a may totally join with the source 24, resulting in a very low resistance source-to-source contact connection. In other embodiments, a gap (not shown) may be maintained under the poly1 layer 36.

Making a low resistance electrical connection path between source contact to source rail by using a source strap cell may result in lower resistance in some embodiments. A source cell may be a good conductor and may retain this property during cell operation since it does not program due to the low voltage difference across it which will not allow hot electrons to be formed in some embodiments. In addition, when reading or programming a cell, the source strap cell's gate may be biased high, which improves its conduction. At each erase, the cell threshold voltage may get more negative, which may make it conduct even more. For dual or more source cell options, resistance may be improved with redundancy.

The source strap cell may be conductive so that its resistance is less than a few kiloOhms or less in some embodiments. Using a masked implant before the tunnel oxide is formed to make the source strap cell may result in significant negative threshold voltages. The angled source/drain implant I, after the cell gate is patterned, may be used to lower its threshold voltage, even up to a negative value, by shortening the electrical channel length. This can be done with a special mask or by modifying the source implant mask. The critical dimensions of the source strap cell may be reduced to reduce the electrical channel and reduce the threshold voltage. Using two or more source strap cells in parallel may reduce masking registration requirements and increase process robustness in some embodiments.

When using two source strap cells in parallel, an implant into the isolation area between conductive regions may create a buried source grid which further enhances robustness. This implant may be done before the trench isolation is filled, but can also be done later using source etch to remove isolation between two parallel source cells with high energy and angled implants.

During sort, overerasing the source strap cells may reduce their threshold voltage, while never programming them again. During cycling, their conductivity may only further improve since in each cycle they will be further erased, lowering their threshold voltage, so that the threshold voltages end up at negative values.

Increasing the drive current of the source strap cells or lowering the source strap cell's threshold voltage relative to the other memory cells may be done by conventional methods such as gate doping, gate material change, modified gate oxide thickness, changing the oxide material or dielectric constant, changing interfacial charge, bulk doping level, surface doping level, or even by making geometrical changes like widening the cells, putting more cells in parallel, increasing source cell mobility by stress, implant, or other means. As another alternative, the source cell gate oxide may be removed below the poly1 or an oxide, nitride, oxide (ONO) layer.

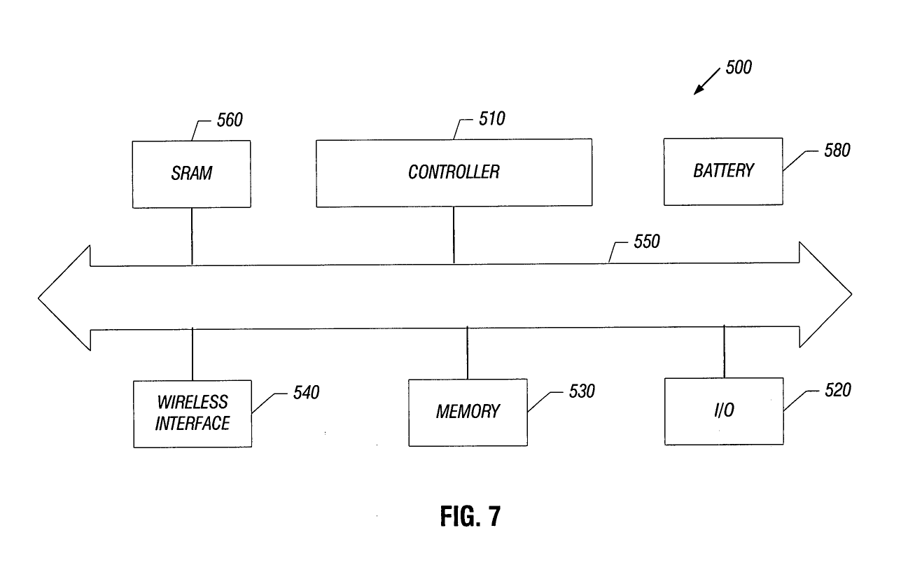

Turning to FIG. 7, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) device 520 (e.g. a keypad, display), a memory 530, a wireless interface 540, a digital camera 550, and a static random access memory (SRAM) 560 and coupled to each other via a bus 550. A battery 580 may supply power to the system 500 in one embodiment. It should be noted that the scope of the present invention is not limited to embodiments having any or all of these components.

Controller 510 may comprise, for example, one or more microprocessors, digital signal processors, micro-controllers, or the like. Memory 530 may be used to store messages transmitted to or by system 500. Memory 530 may also optionally be used to store instructions that are executed by controller 510 during the operation of system 500, and may be used to store user data. The instructions may be stored as digital information and the user data, as disclosed herein, may be stored in one section of the memory as digital data and in another section as analog memory. As another example, a given section at one time may be labeled as such and store digital information, and then later may be relabeled and reconfigured to store analog information. Memory 530 may be provided by one or more different types of memory. For example, memory 530 may comprise a volatile memory (any type of random access memory), or a non-volatile memory such as a flash memory of the type shown in FIG. 1.

The I/O device 520 may be used to generate a message. The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect. Also, the I/O device 520 may deliver a voltage reflecting what is stored as either a digital output (if digital information was stored), or it may be analog information (if analog information was stored).

While an example in a wireless application is provided above, embodiments of the present invention may also be used in non-wireless applications as well.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a flash memory with straight word lines and bitlines.

2. The method of claim 1 including forming a source strap cell to make contact to a source region of the flash memory.

3. The method of claim 2 including forming said source strap cell with a vertical via to contact the source.

4. The method of claim 3 including using an identically formed via to contact the drain.

5. The method of claim 4 including forming a source contact diffusion associated with said via.

6. The method of claim 5 including merging said source contact diffusion to the source of a flash memory cell.

7. The method of claim 6 including forming said source contact diffusion to extend under a gate electrode.

8. The method of claim 6 including forming said source contact diffusion using an angled implant.

9. The method of claim 1 including embedding source contacts between drain contacts.

10. The method of claim 9 including forming said source contacts identically to said drain contacts.

11. A flash memory comprising:
an array of bitlines; and
an array of word lines transverse to said bitlines, said word lines and said bitlines being straight and free of offsets.

12. The memory of claim 11 including a plurality of via contacts, said memory including a plurality of cells each including a source and a drain.

13. The memory of claim 12 wherein said via contacts to said source and said drain are the same.

14. The memory of claim 13 including a source contact diffusion electrically coupled to said via.

15. The memory of claim 14 wherein said source contact diffusion is electrically coupled to said source.

16. The memory of claim 15 wherein said cells include gates and said source contact diffusions extend under said gates.

17. The memory of claim 16 including providing source contacts between drain contacts.

18. A system comprising:
a processor;
a flash memory coupled to said processor, said flash memory including transverse word lines and bitlines, said word lines and bitlines being straight and free of divergence; and
a wireless interface coupled to said processor.

19. The system of claim 18 wherein said flash memory includes vertical vias, sources, drains, and gates.

20. The system of claim 19 wherein said vias to said sources and drains are the same.

21. The system of claim 19 including a source contact diffusion coupled to one of said vias.

22. The system of claim 21 wherein said source contact diffusion contacts said source.
